(19) United States
(12) Patent Application Publication
(10) Pub. No.: US 2011/0156151 A1
(43) Pub. Date: Jun. 30, 2011

(54) Electrode Pick Up Structure In Shallow Trench Isolation Process

(76) Inventors: Tzuyin CHIU, Shanghai (CN); TungYuan Chu, Shanghai (CN); YungChieh Fan, Shanghai (CN); Wensheng Qian, Shanghai (CN); Jiong Xu, Shanghai (CN); Fan Chen, Shanghai (CN); Haifang Zhang, Shanghai (CN)

(21) Appl. No.: 12/979,674

(22) Filed: Dec. 28, 2010

(30) Foreign Application Priority Data
Dec. 31, 2009 (CN) 200910202066.8

(51) Int. Cl. H01L 29/772; H01L 29/70

(52) U.S. Cl. 257/368; 257/526; 257/E29.171; 257/E29.242

(57) ABSTRACT

This invention disclosed a kind of electrode pick up structure in shallow trench isolation process. The active region is isolated by shallow trench. A pseudo-buried layer under the bottom of shallow trench is formed. The pseudo-buried layer extends into active region and connects to doping region one which needs to be picked up by an electrode. The pick up is realized by deep trench contacts which etch through STI and get in touch with pseudo buried layer. This invention can reduce the device size, pick up electrode resistance, collector parasitic capacitance, and increase device cut off frequency.

The current invention claims a foreign priority to application of China 200910202066.8 filed on Dec. 31, 2009.

### FIELD OF THE INVENTION

This invention relates to a kind of semiconductor integrated circuit device. More particularly it relates to one type of electrode pick up structure in shallow trench isolation process and its fabrication method.

### BACKGROUND OF THE INVENTION

A conventional bipolar transistor is illustrated in FIG. 1. Active region is isolated by shallow trench 104. The bipolar transistor includes a collector region 102, a base region 105, and an emitter region 107. The collector region 102 is consisted of an epitaxy layer, which connects to a high doped buried layer 101 at bottom. The collector region 102 is connected to a high energy implanted active region 103 via buried layer 101, the collector is picked up by forming a contact on the high energy implanted active region 103. The base is formed on top of collector region 102, including an intrinsic base 105 and an extrinsic base 106. The intrinsic base 105 is in conjunction with the collector region 102, and is picked up by extrinsic base region 106 and a metal contact on extrinsic base. The emitter region 107 is formed on top of base region 105, and is picked up directly as an emitter by metal contact. Dielectric layer 108 is the isolation material between emitter 107 and intrinsic base 105. As the collector is picked up by a metal contact to high energy implanted region 103, through buried layer 101, bypasses the STI 104, to the collector active region 102, the total device area is large, which induces high collector parasitic capacitance.

### SUMMARY OF THE INVENTION

Present invention gives a technical solution of an electrode output structure in STI isolation process. It can reduce overall device size, reduce collector electrode pick up resistance and collector parasitic capacitance, and preserve good cut off frequency.

To resolve above mentioned technical issues, the electrode picking up structure in STI process by this invention, active region is isolated by STI. A first conduction type pseudo-buried layer is formed beneath STI. The pseudo-buried layer extends to first conduction type doped active region one. A deep trench contact is made through STI, and lead out doped region one through pseudo-buried layer.

The pseudo buried layer is an ion implant layer of the first conduction type. It can be either N type or P type. Its doping concentration should satisfy the formation of ohmic contact between the doping area and metal.

The deep trench contact is a deep trench hole filled with titanium/titanium nitride (Ti/TiN) barrier metal and metal tungsten.

The pseudo-buried layer is formed after the formation of shallow trench and before trench oxide deposition. It is an ion implantation region beneath the shallow trench. After subsequent thermal anneal process, the pseudo-buried layer extends into active region laterally by diffusion and connects to the doping region one.

The doping region one is an ion implantation layer.

The electrode pick up structure is a collector extraction structure of a bipolar transistor. The doping region one is the collector of the bipolar transistor.

The electrode pick up structure is a substrate extraction structure in a MOS transistor. The substrate which is also referred to as doping region one is the channel region between source and drain of the MOS transistor. The substrate can either be an n-well or p-well, in which N well corresponds to PMOS transistor and P well corresponds to NMOS transistor.

In present invention, the pick up electrode to doped region one in active is formed by the deep trench contact through STI and connect to pseudo buried layer. Compared to existing way of electrode pick up approach, such as existing bipolar transistor collector pick up, in which collector region connects to the buried layer and bypasses STI, then links with high energy ion implant layer and finally to contact, present invented electrode pick up can dramatically reduce device size. At the same time the deep trench contact hole is close to device active region, device collector connection path resistance and parasitic capacitance can be decreased, and device cut off frequency can be increased.

### BRIEF DESCRIPTION OF THE DRAWINGS

The foregoing and the object, features, and advantages of the invention will be apparent from the following detailed description of the invention, as illustrated in the accompanying drawings, in which:

FIG. 1 is the existing bipolar transistor structure drawing;

FIG. 2 is this invention's first implementation example structure drawing;

FIG. 3A-FIG. 3E is this invention's first implementation example manufacturing process flow structure drawing;

FIG. 4 is this invention's second implementation example structure drawing.

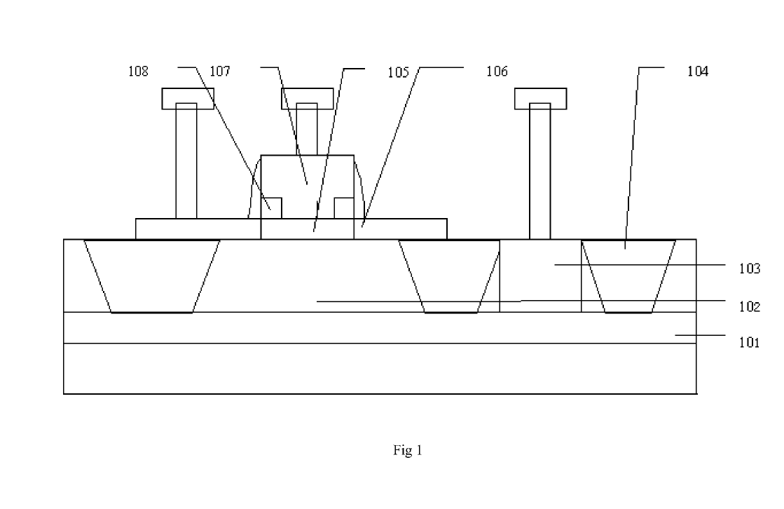

### EXPLANATION OF LABELS IN THE ATTACHED FIGURE

| | |
|---|---|
| 101: heavily doped buried layer | 102: collector region |
| 103: high energy implanted region | 104: shallow trench isolation |
| | region |
| 105: intrinsic base | 106: extrinsic base |
| 107: emitter region | 108: isolation region |
| 201: active region | 202: pseudo-buried layer |
| 203: deep trench contact | 204: shallow trench isolation |
| | region |
| 205: intrinsic base | 206: extrinsic base |
| 207: emitter region | 208: emitter region insulator |
| | layer |
| 209: ILD | 210: ion implanted region one |
| 401: active region | 402: pseudo-buried layer |
| 403: deep trench contact hole | 404: shallow trench isolation |
| | region |
| 209: ILD | 410: N/P well |

### DETAILED DESCRIPTION OF THE INVENTION

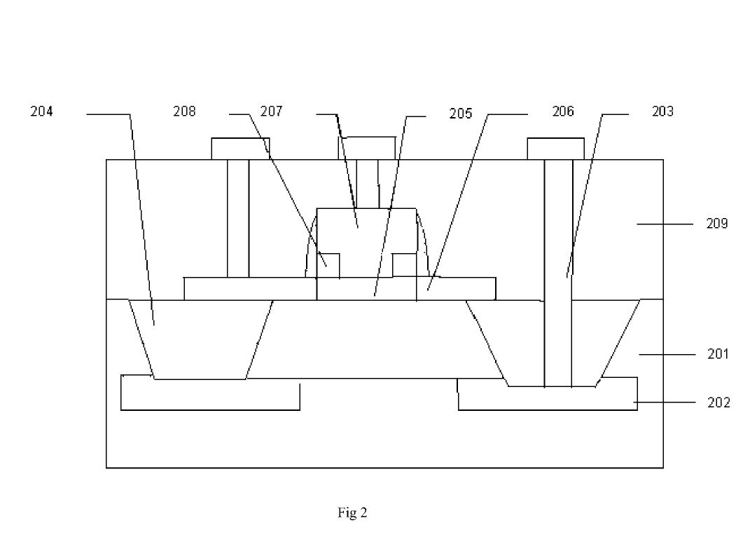

As shown in FIG. 2, it is a structural illustration of the first implementation of present invention. It is a bipolar transistor. Its active region 201 is isolated by STI 204. The bipolar transistor includes a collector region 210, a base region and an emitter region 207. The collector region 210 corresponds to doped region one. The base region is formed by a second conduction type epitaxy layer which is above the collector region 210. The base region includes an intrinsic base 205 and an extrinsic base 206. The intrinsic base 205 is in conjunction with collector region 210. The base is picked up by a metal contact hole to extrinsic base 206. The emitter 207 is formed by a first conduction type polysilicon on top of base. The emitter is picked up by a metal contact formed directly on top of polysilicon. The collector 210 is the above referred doped region one of present invention, consists of first conduction type ion implantation layer, and connect to first conduction type pseudo buried layer 202 at bottom.

For NPN bipolar transistor, the referred first conductive type is N-type and the referred second conductive type is P-type. For PNP bipolar transistor, the referred first conductive type is P-type and the referred second conductive type is N-type. The pseudo buried layer 202 is formed at the bottom of shallow trench 204 by ion implantation, which will laterally diffuse into active region in subsequent thermal process, and make the pseudo buried layer 202 connecting with ion implantation layer of collector region 210. The collector region is picked up by making deep trench contact 203 in oxide layer of shallow trench 204 and connects with pseudo-buried layer 202. The referred deep trench contact 203 is formed by filling Titanium-titanium nitride (Ti/TiN) barrier metal layer and Tungsten into deep trench hole. The referred deep trench contact 203 penetrates inter layer dielectric (ILD) film 209 and oxide layer of shallow trench.

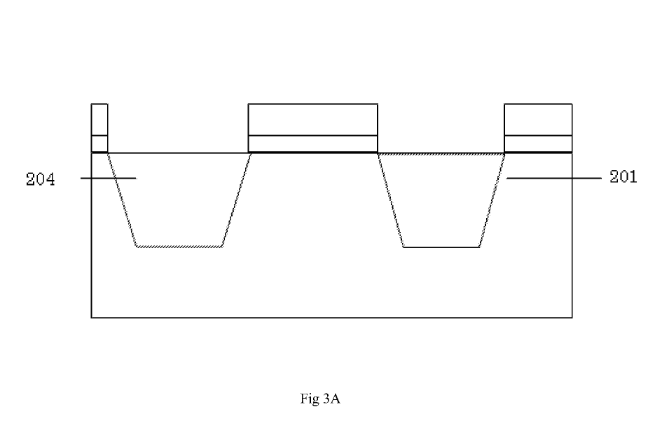

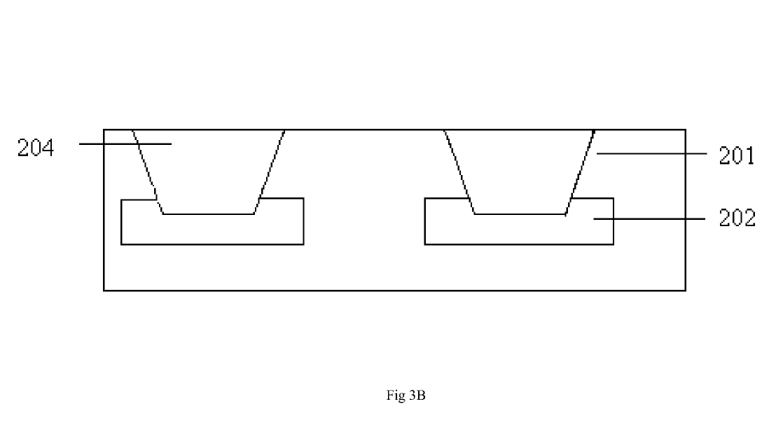

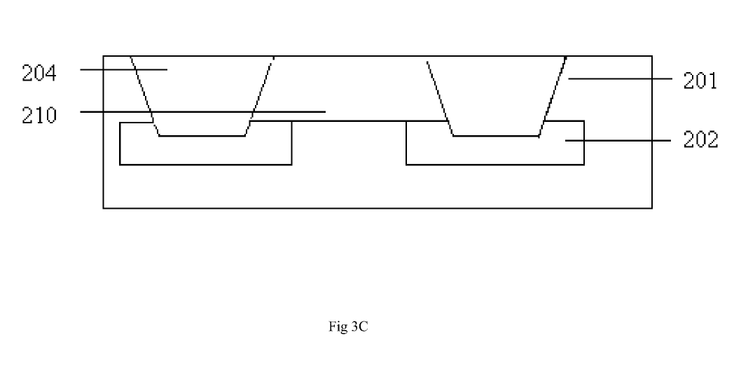

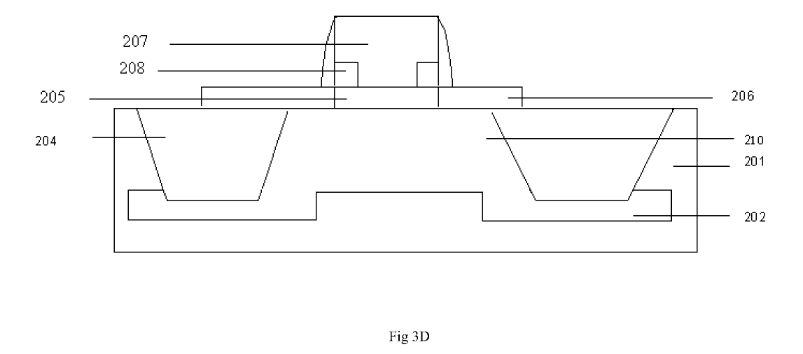

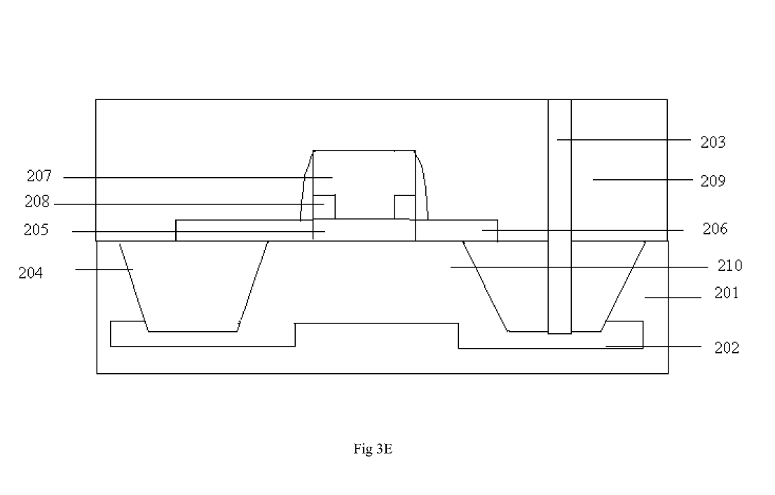

FIG. 3A-FIG. 3E are the manufacturing process flow structure of the first implementation. Following procedures are included:

1. Refer to FIG. 3A: the formation of shallow trench 204 and active region 201. Conventional shallow trench isolation process is adopted here. Hard mask has not been removed at this stage.
2. Refer to FIG. 3B, hard mask or photo resist are used as block layers of active region for ion implantation of high dose first conductive type. The dosage of impurity ions is 1E14˜1E16 cm-2. The referred impurity ions are implanted into the bottom of shallow trench 204, and forms low resistance pseudo buried layer 202. The impurity ions will diffuse into active region in subsequent thermal process. Then the hard mask is removed. For NPN bipolar transistor, the referred first conduction type is N-type and the second conduction type is P-type. For PNP bipolar transistor, the referred first conduction type is P-type and the second conductive type is N-type.
3. Refer to FIG. 3C, the collector region 210 is formed by first conductive type impurity ion implantation.
4. Refer to FIG. 3D, intrinsic base region 205, extrinsic base 206, emitter 207, and isolation layer 208 between base and collector are all formed.
5. Refer to FIG. 3E, inter layer dielectric (ILD) film 209 is formed. Deep trench contact etch is performed to the oxide layer of STI 204 on top of pseudo buried layer 202. Dry etch is adopted. The deep contact penetrates ILD 209 and STI 204, and finally touch pseudo buried layer 202. The deep trench contact hole is then filled with barrier metal Ti/TiN and metal tungsten to form deep contact pick up 203.
6. Refer to FIG. 2, metallic contact is formed on above mentioned base and emitter. The first implementation device type of present invention is completed.

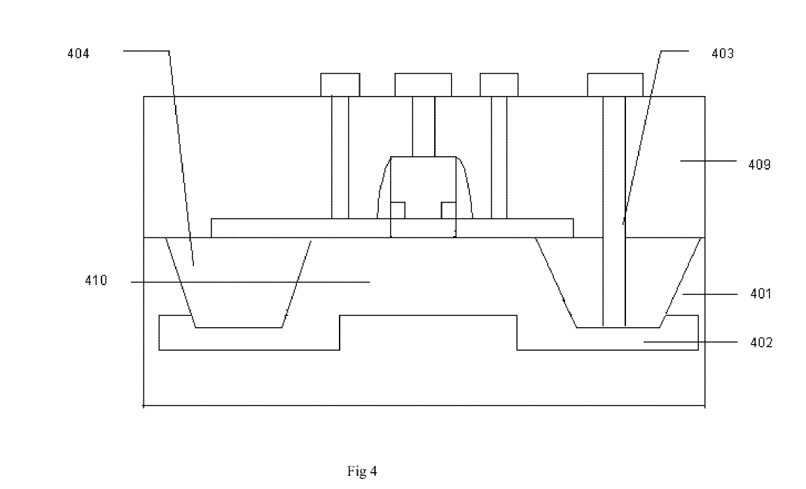

FIG. 4 shows the figure of structure of the second implementation of this invention. It is the substrate extraction structure of MOS transistor in shallow trench isolation process. The MOS transistor is formed in the active region of shallow trench isolation 404. Its source and drain are extracted directly through a metal contact. Substrate is picked up through deep trench contact 403 which penetrates shallow trench isolation 404 and connects with pseudo-buried layer 402, the pseudo buried layer connects with N-well or P-well and form the metallic pick up. The referred N-well or P-well 401 corresponds to doping region one. N-well corresponds to PMOS transistor and P-well corresponds to NMOS transistor.

Above invention has been detailed by concrete implementation examples. However the invention is by no means restricted by above descriptions. Technical staffs in this area can make various deformation and improvement under this principle. These deformation and improvement should be considered as within the scope of this invention.

1. An electrode pick up structure in a shallow trench isolation (STI) process, comprises: an active region isolated by shallow trench; a pseudo-buried layer of the first conduction type formed under the bottom of STI, a deep trench contact exist in STI;
wherein the pseudo-buried layer extends to the active area and connects to the doping region one of the first conduction type which needs to be picked up by an electrode,
the deep trench contact connects to the pseudo-buried layer, the deep trench contact connects out the electrode of doping region one.

2. The electrode pick up structure in a STI process of claim 1 comprises: the pseudo buried layer is an ion implant layer of the first conduction type, the pseudo buried layer is either N type or P type, a doping concentration of the pseudo buried layer should satisfy the formation of ohmic contact of the dope region with metal that fills the deep trench contact.

3. The electrode pick up structure in a STI process of claim 1 comprises: the deep trench contact consists of a deep trench hole filled with Titanium/titanium nitride (Ti/TiN) barrier metal and tungsten (W).

4. The electrode pick up structure in a STI process of claim 1 comprises: the pseudo buried layer is consisted of a diffusion region of ion implantation area beneath the shallow trench after subsequent thermal annealing process, the pseudo buried layer diffuses laterally into active region and links with doping region one.

5. The electrode pick up structure in a STI process of claim 1 comprises: the doping region one is an ion implanted layer.

6. The electrode pick up structure in a STI process of claim 1 comprises: the electrode pick up structure is an output structure of collector of a bipolar transistor; and
the doped region one is a collector region of the bipolar transistor.

7. The electrode pick up structure in a STI process of claim 1 comprises: the electrode pick up structure is an output structure of a substrate of a MOS transistor;
the doping region one is the substrate of the MOS transistor that forms a channel between source and drain of the MOS transistor; the substrate can be either an n-well or a p-well,
the n-well corresponds to a PMOS transistor and the p-well corresponds to a NMOS transistor.
